(19) United States
(12) Patent Application Publication
(10) Pub. No.: US 2012/0325534 A1
(43) Pub. Date: Dec. 27, 2012

(54) METHOD FOR PRODUCING LIQUID CRYSTAL POLYESTER-IMPREGNATED BASE MATERIAL

(75) Inventors: Toyonari ITO, Tsukuba-shi (JP); Changbo SHIM, Daejeon-shi (KR)

(73) Assignee: SUMITOMO CHEMICAL COMPANY, LIMITED, Tokyo (JP)

(21) Appl. No.: 13/524,526

(22) Filed: Jun. 15, 2012

(30) Foreign Application Priority Data
Jun. 22, 2011 (JP) 2011-138224

(51) Int. Cl. B05D 5/06; B05D 3/02; H05K 1/05

(52) U.S. Cl. 174/258; 427/162

(57) ABSTRACT

Disclosed are a method for producing a liquid crystal polyester-impregnated base material, which includes the following steps of (1) impregnating a sheet-like base material composed of a fiber with a liquid composition containing 15 to 45% by mass of a liquid crystal polyester and 55 to 85% by mass of a solvent (based on 100% by mass in total of the liquid crystal polyester and the solvent); (2) allowing the base material impregnated with the liquid composition to pass through a pair of rolls having a distance which is smaller than the thickness of the base material; and (3) heating the liquid composition-impregnated base material passed through rolls at 140 to 250° C. for 60 to 600 seconds; and a printed circuit board including the liquid crystal polyester-impregnated base material produced by the method as an insulating layer.

### BACKGROUND OF THE INVENTION

1. Field of the Invention

The present invention relates to a method for producing a liquid crystal polyester-impregnated base material, and a printed circuit board including the liquid crystal polyester-impregnated base material produced by the method as an insulating layer. The liquid crystal polyester-impregnated base material means a base material impregnated with a liquid crystal polyester.

2. Description of the Related Art

A printed circuit board including an insulating layer made of an insulating base material obtained by impregnating a sheet-like base material with a resin, and a metal layer provided on the insulating layer undergoes blister due to soldering in case of mounting electronic components on the printed circuit board when voids exist on the insulating layer. This blister (1) may cause peeling of wirings to be formed by patterning of a metal layer, and (2) may cause peeling between insulating base materials when the insulating layer is an insulating layer obtained by laminating plural insulating base materials, resulting in deterioration of performances and reliability of the printed circuit board.

JP-A-62-48550 discloses, as a method of suppressing the existence of voids, a method in which impregnation is performed under an environment under reduced pressure in case of impregnating a sheet-like base material with a resin varnish prepared by dissolving a resin in a solvent. JP-A-2004-188652 discloses a method in which a resin varnish is applied on a sheet-like base material, and then the resin varnish is pushed into the sheet-like base material thereby improving impregnating ability of the resin. However, any of these methods does not necessarily exert sufficient effect of suppressing the existence of voids.

### SUMMARY OF THE INVENTION

Under the above circumstances, the present invention has been made and an object of the present invention is to provide a method for producing a liquid crystal polyester-impregnated base material in which the amount of voids has been remarkably decreased, and a printed circuit board including the liquid crystal polyester-impregnated base material produced by the method as an insulating layer.

The present invention relates to a method for producing a liquid crystal polyester-impregnated base material, which includes the following steps of:

(1) impregnating a sheet-like base material composed of a fiber with a liquid composition containing 15 to 45% by mass of a liquid crystal polyester and 55 to 85% by mass of a solvent based on 100% by mass in total of the liquid crystal polyester and the solvent;
(2) allowing the base material impregnated with the liquid composition to pass through a pair of rolls having a distance which is smaller than the thickness of the base material; and
(3) heating the liquid composition-impregnated base material passed through rolls at 140 to 250° C. for 60 to 600 seconds.

The present invention is also directed to a printed circuit board including the liquid crystal polyester-impregnated base material produced by the above method as an insulating layer.

### BRIEF DESCRIPTION OF THE DRAWINGS

FIG. 1 is a schematic view illustrating a method in which the steps (1) and (2) according to the present invention are continuously performed using a long sheet-like base material, in which the reference 3 denotes a dipping bath, 5 denotes a squeeze roll, 5A and 5B denote a roll, 10 denotes a base material, 11 denotes a base material immediately after impregnation with a liquid composition, 12 denotes a liquid composition-impregnated base material, W denotes a liquid composition and G₁ denotes a guide roller, respectively; and

FIG. 2 and FIG. 3 are imaging data of cross sections of liquid crystal polyester-impregnated base materials obtained in Example 4 and Comparative Example 4 by a scanning electron microscope, respectively, in which the references 1 and 1′ denote a liquid crystal polyester-impregnated base material, 1a denotes a warp of a glass cloth, 1b denotes a weft of a glass cloth, 1c denotes a liquid crystal polyester and 2 denotes voids, respectively.

### DETAILED DESCRIPTION OF THE INVENTION

According to the present invention, it is possible to obtain a liquid crystal polyester-impregnated base material in which the amount of voids has been remarkably decreased by using a liquid composition containing a liquid crystal polyester and a solvent in a specific mixing ratio in the step (1), and heating a liquid composition-impregnated base material at a specific temperature for a specific time in the step (3).

The liquid crystal polyester according to the present invention is preferably a liquid crystal polyester which exhibits mesomorphism in a molten state, and melts at a temperature of 450° C. or lower. The liquid crystal polyester may be a liquid crystal polyesteramide, a liquid crystal polyesterether, a liquid crystal polyester carbonate or a liquid crystal polyesterimide. The liquid crystal polyester is preferably a whole aromatic liquid crystal polyester using only an aromatic compound as a raw monomer.

Typical liquid crystal polyester includes the following liquid crystal polyesters:

(I) a liquid crystal polyester obtained by polycondensation (hereinafter referred simply to as “polymerization”) of an aromatic hydroxycarboxylic acid, an aromatic dicarboxylic acid, and at least one kind of a compound selected from the group consisting of an aromatic diol, an aromatic hydroxyamine and an aromatic diamine;

(II) a liquid crystal polyester obtained by polymerizing plural kinds of aromatic hydroxycarboxylic acids;

(III) a liquid crystal polyester obtained by polymerizing an aromatic dicarboxylic acid with at least one kind of a compound selected from the group consisting of an aromatic diol, an aromatic hydroxyamine and an aromatic diamine; and

(IV) a liquid crystal polyester obtained by polymerizing a polyester such as polyethylene terephthalate with an aromatic hydroxycarboxylic acid.

Herein, an aromatic hydroxycarboxylic acid, an aromatic dicarboxylic acid, an aromatic diol, an aromatic hydroxyamine and an aromatic diamine, each independently, may be partially or entirely converted into a polymerizable derivative thereof.

Examples of the polymerizable derivative of compounds having a carboxyl group, such as an aromatic hydroxycarboxylic acid and an aromatic dicarboxylic acid include a derivative (ester) in which a carboxyl group is converted into an alkoxycarbonyl group or an aryloxycarbonyl group, a derivative (acid halide) in which a carboxyl group is converted into a haloformyl group, and a derivative (acid anhydride) in which a carboxyl group is converted into an acyloxycarbonyl group.

Examples of the polymerizable derivative of compounds having a hydroxyl group, such as an aromatic hydroxycarboxylic acid, an aromatic diol and an aromatic hydroxyamine include a derivative (acylate) in which a hydroxyl group is converted into an acyloxyl group by acylation.

Examples of the polymerizable derivative of compounds having an amino group, such as an aromatic hydroxyamine and an aromatic diamine include a derivative (acylate) in which an amino group is converted into an acylamino group by acylation.

The liquid crystal polyester preferably includes a repeating unit represented by the formula (1) shown below (hereinafter referred to as a “repeating unit (1)”), and more preferably include a repeating unit (1), a repeating unit represented by the formula (2) shown below (hereinafter referred to as a “repeating unit (2)”) and a repeating unit represented by the formula (3) shown below (hereinafter referred to as a “repeating unit (3)”):

—O—Ar¹—CO—, (1)

—CO—Ar²—CO—, (2)

—X—Ar³—Y—, and (3)

—Ar⁴—Z—Ar⁵— (4)

wherein Ar¹ is a phenylene group, a naphthylene group, or a biphenylylene group; Ar² and Ar³ each independently represents a phenylene group, a naphthylene group, a biphenylylene group, or a group represented by the above formula (4); X and Y each independently represents an oxygen atom or an imino group; Ar⁴ and Ar⁵ each independently represents a phenylene group or a naphthylene group; Z is an oxygen atom, a sulfur atom, a carbonyl group, a sulfonyl group, or an alkylidene group; and one or more hydrogen atom(s) in Ar¹, Ar² or Ar³, each independently, may be substituted with a halogen atom, an alkyl group, or an aryl group.

Examples of the halogen atom include a fluorine atom, a chlorine atom, a bromine atom and an iodine atom. Examples of the alkyl group include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, a 2-ethylhexyl group, an n-octyl group, an n-nonyl group and an n-decyl group, each preferably having 1 to 10 carbon atoms. Examples of the aryl group include a phenyl group, an o-tolyl group, an m-tolyl group, a p-tolyl group, a 1-naphthyl group and a 2-naphthyl group, each preferably having 6 to 20 carbon atoms.

In case the hydrogen atom is substituted with these groups, the number of groups, each independently, is preferably 2 or less, and more preferably 1, every group represented by Ar¹, Ar² or Ar³.

Examples of the alkylidene group include a methylene group, an ethylidene group, an isopropylidene group, an n-butylidene group and a 2-ethylhexylidene group, each preferably having 1 to 10 carbon atoms.

The repeating unit (1) is a repeating unit derived from an aromatic hydroxycarboxylic acid. The repeating unit (1) is preferably a repeating unit derived from p-hydroxybenzoic acid (repeating unit in which Ar¹ is a 1,4-phenylene group), or a repeating unit derived from 6-hydroxy-2-naphthoic acid (repeating unit in which Ar¹ is a 2,6-naphthylene group).

The repeating unit (2) is a repeating unit derived from an aromatic dicarboxylic acid. The repeating unit (2) is preferably a repeating unit derived from terephthalic acid (repeating unit in which Ar² is a 1,4-phenylene group), a repeating unit derived from isophthalic acid (repeating unit in which Ar² is a 1,3-phenylene group), a repeating unit derived from 2,6-naphthalenedicarboxylic acid (repeating unit in which Ar² is a 2,6-naphthylene group), or a repeating unit derived from diphenylether-4,4′-dicarboxylic acid (repeating unit in which Ar² is a diphenylether-4,4′-diyl group).

The repeating unit (3) is a repeating unit derived from an aromatic diol, an aromatic hydroxylamine or an aromatic diamine. The repeating unit (3) is preferably a repeating unit derived from hydroquinone, p-aminophenol or p-phenylenediamine (repeating unit in which Ar³ is a 1,4-phenylene group), or a repeating unit derived from 4,4′-dihydroxybiphenyl, 4-amino-4′-hydroxybiphenyl or 4,4′-diaminobiphenyl (repeating unit in which Ar³ is a 4,4′-biphenylylene group).

The content of the repeating unit (1) in the liquid crystal polyester is preferably 30 mol % or more, more preferably from 30 to 80 mol %, still more preferably from 30 to 60 mol %, and particularly preferably from 30 to 40 mol %, based on the total amount of all repeating units constituting a liquid crystal polyester (value in which the mass of each repeating unit constituting a liquid crystal polyester is divided by a formula weight of each repeating unit thereof to determine the amount (mol) corresponding to the amount of a substance of each repeating unit, and then the obtained amounts are totalized). Each content of the repeating units (2) and (3) is preferably 35 mol % or less, more preferably from 10 to 35 mol %, still more preferably from 20 to 35 mol %, and particularly preferably from 30 to mol %. When the content of the repeating unit (1) becomes larger, heat resistance, strength and rigidity of the liquid crystal polyester are likely to be improved. However, when the content is too large, solubility of the liquid crystal polyester in a solvent is likely to decrease.

The ratio (content of the repeating unit (2)/content of the repeating unit (3) of the content of the repeating unit (2) to the content of the repeating unit (3) is preferably from 0.9/1.0 to 1.0/0.9, more preferably from 0.95/1.00 to 1.00/0.95, and still more preferably from 0.98/1.00 to 1.00/0.98.

The liquid crystal polyester, each independently, may include two or more kinds of the repeating units (1) to (3). The liquid crystal polyester may include a repeating unit other than the repeating units (1) to (3), and the content thereof is preferably 10 mol % or less, and more preferably 5 mol % or less.

From the viewpoint of the liquid crystal polyester having excellent solubility in a solvent, X and/or Y of at least a part of the repeating unit (3) is/are preferably imino group(s) (—NH—) (that is, a repeating unit derived from an aromatic hydroxylamine and/or a repeating unit derived from an aromatic diamine is/are preferably included), X and/or Y of the entire repeating unit (3) is/are more preferably imino group(s) (—NH—).

The liquid crystal polyester is preferably produced by melt polymerization of raw monomers to obtain a polymer (hereinafter referred to as a “prepolymer”), followed by solid-phase polymerization of the prepolymer. It is possible to produce a high-molecular weight liquid crystal polyester having high heat resistance, strength and rigidity with satisfactory operability by this production method. The melt polymerization may be performed in the presence of a catalyst, and examples of the catalyst include metal compounds such as magnesium acetate, stannous acetate, tetrabutyl titanate, lead acetate, sodium acetate, potassium acetate and antimony trioxide; and nitrogen-containing heterocyclic compounds such as 4-(dimethylamino)pyridine and 1-methylimidazole. Among these compounds, nitrogen-containing heterocyclic compounds are preferable.

The flow initiation temperature of the liquid crystal polyester is preferably 250° C. or higher, more preferably from 250 to 350° C., and still more preferably from 260 to 330° C. When the flow initiation temperature becomes higher, heat resistance, strength and rigidity of the liquid crystal polyester are improved. However, when the flow initiation temperature is too high, solubility of the liquid crystal polyester in a solvent may sometimes decrease, or viscosity of the below-mentioned liquid composition to be used in the step (1) may sometimes increase.

The flow initiation temperature is also called a flow temperature and means a temperature at which a melt viscosity becomes 4,800 Pa·s (48,000 poise) when a liquid crystal polyester is melted while heating at a heating rate of 4° C./min under a load of 9.8 MPa (100 kg/cm²) and extruded through a nozzle having an inner diameter of 1 mm and a length of 10 mm using a capillary rheometer, and the flow initiation temperature serves as an index indicating a molecular weight of the liquid crystal polyester (see “Liquid Crystalline Polymer Synthesis, Molding, and Application” edited by Naoyuki Koide, page 95, published by CMC Publishing Co., Ltd., on Jun. 5, 1987).

The liquid composition to be used in the step (1) is preferably a solution prepared by dissolving a liquid crystal polyester in a solvent. The solvent includes a solvent which dissolves a liquid crystal polyester in the amount of 1% by mass based on 100% by weight in total of the liquid crystal polyester and the solvent.

Examples of the solvent include halogenated hydrocarbons such as dichloromethane, chloroform, 1,2-dichloroethane, 1,1,2,2-tetrachloroethane and o-dichlorobenzene; halogenated phenols such as p-chlorophenol, pentachlorophenol and pentafluorophenol; ethers such as diethylether, tetrahydrofuran and 1,4-dioxane; ketones such as acetone and cyclohexanone; esters such as ethyl acetate and γ-butyrolactone ester; carbonates such as ethylene carbonate and propylene carbonate; amines such as triethylamine; nitrogen-containing heterocyclic aromatic compounds such as pyridine; nitriles such as acetonitrile and succinonitrile; amide-based compounds such as N,N-dimethylformamide, N,N-dimethylacetamide and N-methylpyrrolidone (N-methyl-2-pyrrolidone); urea compounds such as tetramethylurea; nitro compounds such as nitromethane and nitrobenzene; sulfur compounds such as dimethyl sulfoxide and sulfolane; phosphorus compounds such as hexamethylphosphoric acid amide and tri-n-butylphosphoric acid; and two or more combinations thereof.

The solvent is preferably a solvent containing, as a main component, an aprotic compound, and particularly preferably an aprotic compound having no halogen atom, from the viewpoint of easily handling because of low corrosiveness. The content of the aprotic compound is preferably from 50 to 100% by mass, more preferably from 70 to 100% by mass, and still more preferably from 90 to 100% by mass, based on 100% by mass of the entire solvent. The aprotic compound is preferably an amide-based compound such as N,N-dimethylformamide, N,N-dimethylacetamide or N-methylpyrrolidone since it easily dissolves a liquid crystal polyester.

The solvent is preferably a solvent containing, as a main component, a compound of a dipole moment of 3 to 5, from the viewpoint of easily dissolving a liquid crystal polyester. The content of the compound is preferably from 50 to 100% by mass, more preferably from 70 to 100% by mass, and still more preferably from 90 to 100% by mass, based on 100% by mass of the entire solvent. Accordingly, the solvent is more preferably the above-mentioned aprotic compound in which a dipole moment is from 3 to 5.

The solvent is preferably a solvent containing, as a main component, a compound having a boiling point at 1 atm of 220° C. or lower from the viewpoint of easily dissolving a liquid crystal polyester. The content of the compound is preferably from 50 to 100% by mass, more preferably from 70 to 100% by mass, and still more preferably from 90 to 100% by mass, based on 100% by mass of the entire solvent. Accordingly, the solvent is more preferably the above-mentioned aprotic compound in which a boiling point at 1 atmospheric pressure is 220° C. or lower.

The liquid composition contains a liquid crystal polyester in the amount of 15 to 45% by mass, and preferably 20 to 35% by mass, and contains a solvent in the amount of 55 to 85% by mass, and preferably 65 to 80% by mass, based on 100% by mass in total of the liquid crystal polyester and the solvent. When the content is 15% by mass or more, it is possible to impregnate a base material with a sufficient amount of the liquid crystal polyester. When the content is 45% by mass or less, it is possible to easily impregnate a base material with a liquid composition since the viscosity of the liquid composition does not become too high.

The liquid composition may contain one, or a combination of two or more kinds of other components such as a filler, an additive, and a resin other than the liquid crystal polyester.

Examples of the filler include inorganic fillers such as silica, alumina, titanium oxide, barium titanate, strontium titanate, aluminum hydroxide and calcium carbonate; and organic fillers such as a cured epoxy resin, a cross-linked benzoguanamine resin and a cross-linked acrylic resin. The content of the filler is preferably from 0 to 100 parts by weight based on 100 parts by weight of the liquid crystal polyester.

Examples of the additive include a leveling agent, a defoamer, an antioxidant, an ultraviolet absorber, a flame retardant and a colorant. The content of the additive is preferably from 0 to 5 parts by weight based on 100 parts by weight of the liquid crystal polyester.

Examples of the resin other than the liquid crystal polyester include thermoplastic resins such as polypropylene, polyamide, polyester other than the liquid crystal polyester, polyphenylene sulfide, polyetherketone, polycarbonate, polyethersulfone, polyphenyleneether and polyetherimide; and thermosetting resins such as a phenol resin, an epoxy resin, a polyimide resin and a cyanate resin. The content of the resin other than the liquid crystal polyester is preferably from 0 to 20 parts by weight based on 100 parts by weight of the liquid crystal polyester.

The liquid composition can be prepared by mixing a liquid crystal polyester, a solvent and other optional components, collectively or in an appropriate order. When the other component is a filler, the liquid composition is preferably prepared by a method including the steps of dissolving a liquid crystal polyester in a solvent to obtain a liquid crystal polyester solution, and dispersing a filler in the liquid crystal polyester solution.

The sheet-like base material made of a fiber according to the present invention may be any of a textile fabric (woven fabric), a knitted fabric and a nonwoven fabric. Among these fabrics, a textile fabric is preferable since dimensional stability of the below-mentioned liquid crystal polyester-impregnated base material is likely to be improved.

Examples of the fiber include an inorganic fiber, a carbon fiber and an organic fiber. The base material is composed of one kind of a fiber, or a combination of two or more kinds of fibers.

Examples of the inorganic fiber include a glass fiber, an alumina fiber and a ceramic fiber (for example, silicon-containing ceramic fiber). Examples of the organic fiber include a polyester fiber other than a liquid crystal polyester fiber, aramid fiber and a polybenzazole fiber. From the viewpoint of easy availability, the base material according to the present invention is preferably a sheet made mainly of a glass fiber, that is, a glass cloth.

The glass cloth is preferably made of an alkali-containing glass fiber, a non-alkali glass fiber or a low dielectric glass fiber. A part of the fiber constituting the glass cloth may be a fiber other than a glass fiber, such as a ceramic fiber or a carbon fiber. The fiber constituting the glass cloth may be surface-treated with a coupling agent such as an aminosilane-based coupling agent, an epoxysilane-based coupling agent or a titanate-based coupling agent.

Examples of the method for producing a glass cloth include (1) a production method, which includes the steps of (i) dispersing a fiber a fiber which forms a glass cloth in water, (ii) adding, as an optional component, a sizing agent such as an acrylic resin, (iii) subjecting the obtained dispersion to papermaking using a paper machine, and (iv) drying to obtain a nonwoven fabric; and (2) a method using a known weaving machine.

Examples of the weave of a fiber include plain weave, satin weave, twill weave and mat weave. The weave density is preferably from 10 to 100 yarns/25 mm. The mass per unit area of the glass cloth is preferably from 10 to 300 g/m².

The glass cloth may also be a commercially available product. Examples of easily commercially available product include glass cloths for an insulating impregnated base material of electronic components, which are commercially available from manufacturers such as Unitika Limited, Asahi Kasei E-materials Corporation, Nitto Boseki Co., Ltd. and Arisawa Mfg. Co., Ltd. Among commercially available products, examples of a glass cloth having a suitable thickness include glass cloths having IPC designations such as 1035, 1078, 2116 and 7628.

The thickness of the sheet-like base material according to the present invention is preferably from 10 to 200 μm, more preferably from 10 to 180 μm, and still more preferably from 10 to 100 μm.

Examples of the method of impregnating a base material with a liquid composition include a method in which a base material is dipped in a liquid composition in a dipping bath. The amount of a liquid crystal polyester to be coated on the base material can be easily controlled by appropriately controlling (1) the content of a liquid crystal polyester in a liquid composition, (2) a dipping time, and (3) a rate of pulling up a base material from a dipping bath.

The step (2) according to the present invention is the step of removing excess liquid composition adhered on a surface of a base material.

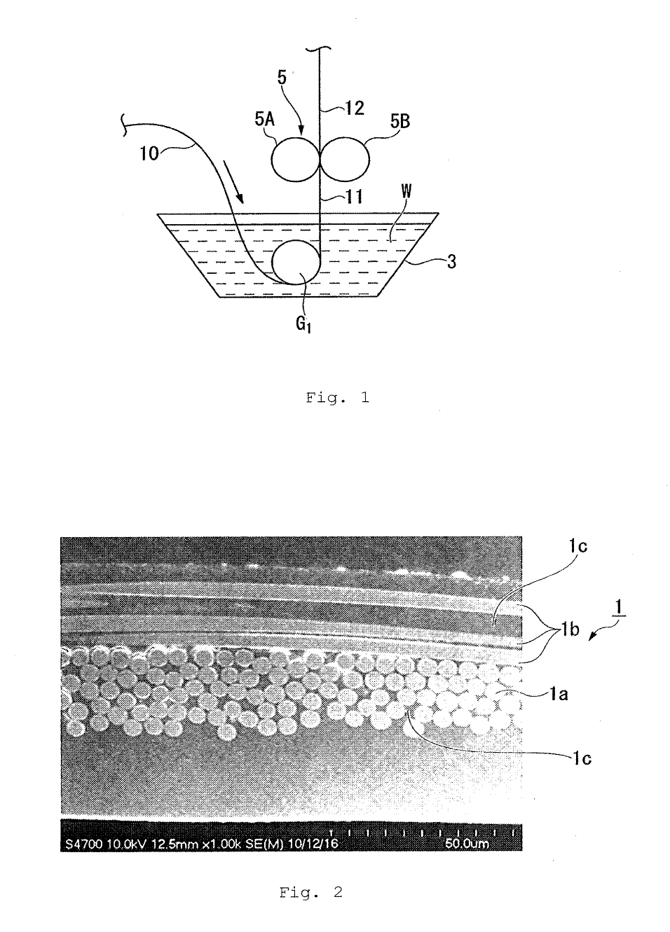

In FIG. 1, a long base material 10 moves in the direction of the arrow while being guided by a guide roller G₁ and dipped in a liquid composition W in a dipping bath 3. The base material 11 impregnated with the liquid composition is fed to a squeeze roll 5 having a distance, which is smaller than the thickness of the base material 11 and is equipped with a pair of a roll 5A and a roll 5B arranged oppositely so as to sandwich the base material 11 therebetween. The base material 11 is squeezed by the squeeze roll 5 to remove excess liquid composition, and thus obtaining a liquid composition-impregnated base material 12 into which the liquid composition is sufficiently impregnated.

The distance between the rolls 5A and 5B can be adjusted according to the thickness of the objective liquid crystal polymer-impregnated base material. The rolls 5A and 5B are rolls which rotate by themselves (self-rotate), or rolls which rotate in association with running of the base material 11. When using the former roll, (1) the coating amount of the liquid composition in the liquid composition-impregnated base material 12 can be easily adjusted, and thus (2) a liquid crystal polymer-impregnated base material having more smooth surface can be obtained.

In case the rolls 5A and 5B self-rotate, the direction of rotation of these rolls is the same as or opposite to the direction of movement of the base material 11. A ratio Y/Z of a peripheral speed Y of the rolls 5A and 5B to a movement speed Z of the base material 11 (the same as a movement speed of a base material 10) is preferably more than 0 and 1.0 or less, and more preferably more than 0 and 0.5 or less. By making a difference between the peripheral speed Y and the movement speed Z so as to satisfy the ratio, the rolls 5A and 5B rotate to the movement of the base material 11, and thus obtaining (1) effect of removing excess liquid composition W, (2) effect of smoothing a surface of a base material 12, and (3) effect in which the base material 12 is less likely to be fractured since excess friction does not arise between a surface of the rolls 5A and 5B and a surface of the base material 12.

The step (3) according to the present invention is the step of heating a liquid composition-impregnated base material 12 at 140 to 250° C. thereby vaporizing and removing a solvent contained therein to stably obtain a liquid crystal polyester-impregnated base material in which the amount of voids has been remarkably decreased. When the temperature is 140° C. or higher, the amount of voids of the obtained liquid crystal polyester-impregnated base material is remarkably decreased. When the temperature is 250° C. or lower, degradation of the liquid crystal polyester in the obtained liquid crystal polyester-impregnated base material can be suppressed.

The heating time of the step (3) is from 60 to 600 seconds, and preferably from 120 to 600 seconds. That is, the production method of the present invention is preferably a production method in which the heating time is from 120 to 600 seconds. When the heating time is 60 seconds or more, the solvent is sufficiently removed, and thus blocking properties (stickiness) between the obtained liquid crystal polyester-impregnated base materials are suppressed. Accordingly, in case a long sheet-like base material as shown in FIG. 1 is used and also the liquid crystal polyester-impregnated base material passed through the step (3) is taken up by a roll (not shown in FIG. 1), blocking properties between the sheet-like base materials thus taken up are suppressed. When the heating time is 600 seconds or less, productivity of the liquid crystal polyester-impregnated base material is improved.

The step (3) is performed in air or under an atmosphere of an inert gas such as a nitrogen gas. From the viewpoint of versatility, the step is preferably performed in air. The step (3) is performed under reduced pressure, ventilation or a combination thereof.

The amount of the liquid crystal polyester contained in the liquid crystal polyester-impregnated base material obtained in the step (3) is preferably from 30 to 80% by mass, and more preferably from 40 to 70% by mass, based on 100% by mass of the liquid crystal polyester-impregnated base material.

The step of heating the liquid crystal polyester-impregnated base material obtained in the step (3) (hereinafter referred to as the “step (4)”) at a temperature higher than 250° C. may be added after the step (3). The molecular weight of the liquid crystal polyester contained in the liquid crystal polyester-impregnated base material obtained in the step (3) is enhanced by the step (4), and thus heat resistance of the liquid crystal polyester-impregnated base material can be more improved.

The step (4) is preferably performed under an atmosphere of an inert gas such as a nitrogen gas. The heating temperature of the step (4) is preferably from 270 to 330° C., and more preferably from 260 to 320° C. When the heating temperature is 270° C. or higher, the molecular weight of the liquid crystal polyester can be sufficiently increased. When the heating temperature is 330° C. or lower, degradation of the liquid crystal polyester can be sufficiently suppressed. The heating time is preferably from 1 to 30 hours, and more preferably from 1 to 10 hours. When the heating time is 1 hour or more, the molecular weight of the liquid crystal polyester can be sufficiently increased. When the heating time is 30 hours, productivity of the liquid crystal polyester-impregnated base material can be improved.

The printed circuit board of the present invention can have the same constitution as that of a known printed circuit board, except that the above liquid crystal polyester-impregnated base material is included as the insulating layer, and can be produced by the same production method as that of a known printed circuit board.

The method for producing a printed circuit board of the present invention includes a method including the step (I) of providing a metal layer on one or both surfaces of an insulating layer made of a piece of the above liquid crystal polyester-impregnated base material, or an insulating layer obtained by laminating two or more plural liquid crystal polyester-impregnated base materials to produce a laminate; the step (II) of forming a predetermined wiring pattern on a metal layer of the laminate by a technique such as etching; and the step (III) of laminating one or two or more laminates with the wiring pattern formed thereon.

In case the insulating layer of the above step (I) is an insulating layer obtained by laminating plural liquid crystal polyester-impregnated base materials, plural liquid crystal polyester-impregnated base materials are the same or different from each other. In this case, the insulating layer can be produced by laying plural liquid crystal polyester-impregnated base materials one upon another in the thickness direction, and then mutually welding the liquid crystal polyester-impregnated base materials through heat pressing, resulting in integration of them.

The material of the metal layer in the above step (I) is preferably copper, aluminum, silver, or an alloy containing one or more kinds of metals selected from them. Among these, copper or a copper alloy is preferred from the viewpoint of excellent conductivity. The metal layer is preferably a metal layer composed of a metal foil, and more preferably metal layer composed of a copper foil, from the viewpoint of ease of handling, simplicity of formation, and excellent economical efficiency. In case the metal layer is provided on both surfaces of the insulating layer, the material of two metal layers is the same or different. The thickness of the metal layer is preferably from 1 to 70 μm, more preferably from 3 to 35 μm, and still more preferably from 5 to 18 μm.

Examples of the method of providing the metal layer include (1) a method in which a metal foil is welded on a surface of an insulating layer by hot pressing, (2) a method in which a metal foil is adhered on a surface of an insulating layer using an adhesive, (3) a method in which a surface of an insulating layer is plated with metal, and (4) a method in which a surface of an insulating layer is coated with a metal powder or metal particles by a screen printing method or a sputtering method.

In case the insulating layer of the above step (I) is an insulating layer formed by laminating plural liquid crystal polyester-impregnated base materials, the laminate of the above step (I) may be produced by arranging in a state of laying all of plural liquid crystal polyester-impregnated base materials one upon another, and arranging a metal foil on one or both surfaces thereof, followed by entire heat-pressing. This production method is a method capable of simultaneously performing the production of the insulating layer and lamination of the metal layer.

Among the above methods (1) to (4) of providing a metal layer, the method (1) is most preferred from the viewpoint of adhesion with the insulating layer.

Since the printed circuit board of the present invention contains, as an insulating layer, a liquid crystal polyester-impregnated base material in which the amount of voids has been remarkably decreased, the generation of blister due to soldering in case of mounting electronic components on the printed circuit board is suppressed. Accordingly, (1) peeling of wirings to be formed of a metal layer from the insulating layer, and (2) peeling between plural insulating base materials when the insulating layer is an insulating layer obtained by laminating plural insulating base materials, is remarkably suppressed, and thus performances and reliability of the printed circuit board are enhanced.

### EXAMPLES

The present invention will be descried below by way of Examples, but the present invention is not limited to these Examples.

### Production Example 1

### (1) Production of Liquid Crystal Polyester

In a reactor equipped with a stirrer, a torque meter, a nitrogen gas introducing tube, a thermometer and a reflux condenser, 1,976 g (10.5 mol) of 6-hydroxy-2-naphthoic acid, 1,474 g (9.75 mol) of 4-hydroxyacetoanilide, 1,620 g (9.75 mol) of isophthalic acid and 2,374 g (23.25 mol) of acetic anhydride were charged. After sufficiently replacing the gas in the reactor by a nitrogen gas, the temperature was raised from room temperature to 150° C. over 15 minutes while stirring under a nitrogen gas flow, and the mixture was refluxed at 150° C. for 3 hours.

While distilled off the by-produced acetic acid and the unreacted acetic anhydride, the temperature was raised from 150° C. to 300° C. over 2 hours and 50 minutes and, after maintaining at 300° C. for 1 hour, the reaction mixture was taken out from the reactor. The reaction mixture was cooled to room temperature and the obtained solid matter was crushed by a crusher to obtain a powdered prepolymer. The prepolymer showed a flow initiation temperature of 235° C. The temperature was raised from room temperature to 223° C. over 6 hours in a nitrogen gas atmosphere and solid phase polymerization of the prepolymer was carried out at 223° C. for 3 hours, followed by cooling to obtain a powdered liquid crystal polyester. The liquid crystal polyester showed a flow initiation temperature of 270° C.

### (2) Production of Liquid Composition

The obtained liquid crystal polyester (2,200 g) was added to N,N-dimethylacetamide (solvent) (7,800 g), followed by heating at 100° C. for 2 hours to obtain a liquid composition (1) having a content of a liquid crystal polyester of 22% by mass (based on 100% by mass in total of a liquid crystal polyester and a solvent) in the form of a solution.

In the same manner, the liquid crystal polyester obtained above (2,900 g) was added to N,N-dimethylacetamide (solvent) (7,100 g), followed by heating at 100° C. for 2 hours to obtain a liquid composition (2) having a content of a liquid crystal polyester of 29% by mass (based on 100% by mass in total of a liquid crystal polyester and a solvent) in the form of a solution.

To this liquid composition (2), silica MP-8FS (having a volume average particle diameter of 0.5 μm) manufactured by TATSUMORI LTD., and then the silica was dispersed by a centrifugal defoamer HM-500 manufactured by KEYENCE CORPORATION to obtain a liquid composition (3) having the content of a liquid crystal polyester of 29% by mass (based on 100% by mass in total of a liquid crystal polyester and a solvent) and having the content of silica of 20% (based on 100% by mass in total of a liquid crystal polyester and silica) at 23° C.

Using a flow tester (Model CFT-500, manufactured by Shimadzu Corporation), the above flow initiation temperature of the liquid crystal polyester was measured by the following procedure. That is, about 2 g of a liquid crystal polyester was filled in a cylinder with a die including a nozzle having an inner diameter 1 mm and a length of 10 mm attached thereto, and the liquid crystal polyester was extruded through the nozzle while melting at a rate of 4° C./minute under a load of 9.8 MPa (100 kg/cm²), and then the temperature at which the liquid crystal polyester shows a viscosity of 4,800 Pa·s (48,000 poise) was measured.

### Example 1

A glass cloth having IPC designation of 1078 manufactured by Unitika Limited was dipped in the above liquid composition (1) at room temperature for 1 minute and then pulled up (step (1)). Thereafter, excess liquid composition adhered on the surface of the glass cloth was removed by allowing the glass cloth to pass through a pair of rolls (step (2)). Then, the solvent was vaporized and removed by heating at 250° C. for 600 seconds using a hot-air dryer manufactured by ESPEC Corp. to obtain a liquid crystal polyester-impregnated base material (step (3)). The amount of the liquid crystal polyester contained in this liquid crystal polyester-impregnated base material was 56% by mass based on 100% by mass of the amount of the liquid crystal polyester-impregnated base material. In order to enhance the molecular weight of the liquid crystal polyester contained therein, the liquid crystal polyester-impregnated base material was further heated at under a nitrogen gas atmosphere at 290° C. for 3 hours using a hot-air dryer (step (4)). The amount of voids of the obtained liquid crystal polyester-impregnated base material was less than 0.01%. The results are shown in Table 1. In all Examples and Comparative Examples in the specification of the present application, the steps (2) and (4) were carried out under the same conditions. Therefore, the steps (2) and (4) are not mentioned in Table 1. “LCP” in Table 1 denotes a liquid crystal polyester.

### Example 2

In the same manner as in Example 1, except that 250° C. in the step (3) was changed to 230° C., a liquid crystal polyester-impregnated base material containing voids in the amount of less than 0.01% was obtained. The results are shown in Table 1.

### Example 3

In the same manner as in Example 1, except that 250° C. in the step (3) was changed to 180° C., a liquid crystal polyester-impregnated base material containing voids in the amount of 0.02% was obtained. The results are shown in Table 1.

### Example 4

In the same manner as in Example 1, except that 250° C. in the step (3) was changed to 150° C., a liquid crystal polyester-impregnated base material containing voids in the amount of 0.07% was obtained. The results are shown in Table 1.

### Example 5

In the same manner as in Example 1, except that 250° C. in the step (3) was changed to 140° C., a liquid crystal polyester-impregnated base material containing voids in the amount of 0.16% was obtained. The results are shown in Table 1.

### Example 6

In the same manner as in Example 1, except that (I) the glass cloth having IPC designation of 1078 manufactured by Unitika Limited was changed to a glass cloth having IPC designation of 2116 manufactured by Unitika Limited, (II) the liquid composition (1) was changed to the liquid composition (2), and (III) 250° C. in the step (3) was changed to 180° C., a liquid crystal polyester-impregnated base material was obtained. The amount of the liquid crystal polyester contained in this liquid crystal polyester-impregnated base material was 45% by mass based on 100% by mass of the amount of the liquid crystal polyester-impregnated base material. The liquid crystal polyester-impregnated base material obtained in the step (3) was treated in the step (4) in the same manner as in Example 1 to obtain a liquid crystal polyester-impregnated base material containing voids in the amount of 0.32%. The results are shown in Table 1.

### Example 7

In the same manner as in Example 1, except that (I) the glass cloth having IPC designation of 1078 manufactured by Unitika Limited was changed to a glass cloth having IPC designation of 2116 manufactured by Unitika Limited, (II) the liquid composition (1) was changed to the liquid composition (2), and (III) 250° C. in the step (3) was changed to 140° C., a liquid crystal polyester-impregnated base material containing voids in the amount of 0.20% was obtained. The results are shown in Table 1.

### Example 8

In the same manner as in Example 1, except that (I) the glass cloth having IPC designation of 1078 manufactured by Unitika Limited was changed to a glass cloth having IPC designation of 2116 manufactured by Unitika Limited, (II) the liquid composition (1) was changed to the liquid composition (3), and (III) 250° C. in the step (3) was changed to 140° C., a liquid crystal polyester-impregnated base material containing voids in the amount of 0.36% was obtained. The results are shown in Table 1.

### Example 9

In the same manner as in Example 1, except that (I) 250° C. in the step (3) was changed to 140° C. and (II) 600 seconds in the step (3) was changed to 120 seconds, liquid crystal polyester-impregnated base material containing voids in the amount of 0.19% was obtained. The results are shown in Table 1.

### Example 10

In the same manner as in Example 1, except that (I) 250° C. in the step (3) was changed to 140° C. and (II) 600 seconds in the step (3) was changed to 240 seconds, liquid crystal polyester-impregnated base material containing voids in the amount of 0.06% was obtained. The results are shown in Table 1.

### Comparative Example 1

In the same manner as in Example 1, except that 250° C. in the step (3) was changed to 40° C., a liquid crystal polyester-impregnated base material containing voids in the amount of 2.44% was obtained. The results are shown in Table 1.

### Comparative Example 2

In the same manner as in Example 1, except that 250° C. in the step (3) was changed to 120° C., a liquid crystal polyester-impregnated base material containing voids in the amount of less than 1.61% was obtained. The results are shown in Table 1.

### Comparative Example 3

In the same manner as in Example 1, except that (I) the glass cloth having IPC designation of 1078 manufactured by Unitika Limited was changed to a glass cloth having IPC designation of 2116 manufactured by Unitika Limited, (II) the liquid composition (1) was changed to the liquid composition (2), and (III) 250° C. in the step (3) was changed to 40° C., a liquid crystal polyester-impregnated base material containing voids in the amount of 4.17% was obtained. The results are shown in Table 1.

### Comparative Example 4

In the same manner as in Example 1, except that (I) the glass cloth having IPC designation of 1078 manufactured by Unitika Limited was changed to a glass cloth having IPC designation of 2116 manufactured by Unitika Limited, (II) the liquid composition (1) was changed to the liquid composition (2), and (III) 250° C. in the step (3) was changed to 120° C., a liquid crystal polyester-impregnated base material containing voids in the amount of 3.24% was obtained. The results are shown in Table 1.

### Comparative Example 5

In the same manner as in Example 1, except that (I) the glass cloth having IPC designation of 1078 manufactured by Unitika Limited was changed to a glass cloth having IPC designation of 2116 manufactured by Unitika Limited, (II) the liquid composition (1) was changed to the liquid composition (3), and (III) 250° C. in the step (3) was changed to 120° C., a liquid crystal polyester-impregnated base material containing voids in the amount of 2.75% was obtained. The results are shown in Table 1.

The amount of voids was measured by the method of the following procedure.

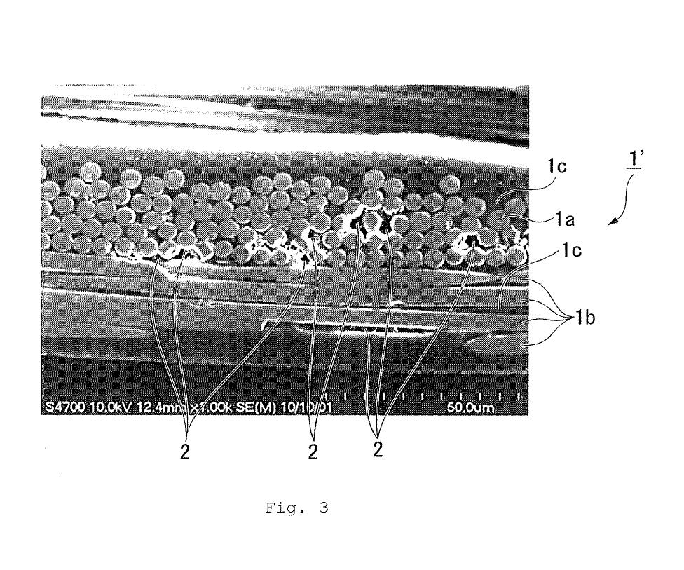

(1) A cross section of each of liquid crystal polyester-impregnated base materials obtained in all Examples and Comparative Examples was imaged by a scanning electron microscopy to obtain imaging data. Imaging data obtained in Example 4 and Comparative Example 4 are shown in FIG. 2 and FIG. 3, respectively as examples of imaging data.

(2) The portion of a void and the portion other than the void of imaging data are binarized.

(3) Using image analyzing program LUZEX manufactured by Nireco Corporation, the area of the void portion is calculated assumed that the total area of the cross section of the liquid crystal polyester-impregnated base material is 100%.

TABLE 1

| | Examples | | | | | | | |
|---|---|---|---|---|---|---|---|---|
| | 1 | 2 | 3 | 4 | 5 | 6 | 7 | 8 |
| Production conditions | | | | | | | | |
| Step (I) | | | | | | | | |
| IPC designation of glass cloth | 1078 | 1078 | 1078 | 1078 | 1078 | 2116 | 2116 | 2116 |
| Liquid composition | | | | | | | | |
| Kind | (1) | (1) | (1) | (1) | (1) | (2) | (2) | (3) |
| Content of LCP (% by mass) | 22 | 22 | 22 | 22 | 22 | 29 | 29 | 29 |
| Step (3) | | | | | | | | |
| Temperature (° C.) | 250 | 230 | 180 | 150 | 140 | 180 | 140 | 140 |
| Time (second) | 600 | 600 | 600 | 600 | 600 | 600 | 600 | 600 |
| Amount of voids (%) | <0.01 | <0.01 | 0.02 | 0.07 | 0.16 | 0.32 | 0.20 | 0.36 |

| | Examples | | Comparative Examples | | | | |
|---|---|---|---|---|---|---|---|
| | 9 | 10 | 1 | 2 | 3 | 4 | 5 |
| Production conditions | | | | | | | |
| Step (I) | | | | | | | |
| IPC designation of glass cloth | 1078 | 1078 | 1078 | 1078 | 2116 | 2116 | 2116 |
| Liquid composition | | | | | | | |
| Kind | (1) | (1) | (1) | (1) | (2) | (2) | (3) |
| Content of LCP (% by mass) | 22 | 22 | 22 | 22 | 29 | 29 | 29 |
| Step (3) | | | | | | | |
| Temperature (° C.) | 140 | 140 | 40 | 120 | 40 | 120 | 120 |
| Time (second) | 120 | 240 | 600 | 600 | 600 | 600 | 600 |
| Amount of voids (%) | 0.19 | 0.06 | 2.44 | 1.61 | 4.17 | 3.24 | 2.75 |

The results shown in Table 1 revealed that the amount of voids of the liquid crystal polyester-impregnated base materials obtained in Examples 1 to 10 is less than 1%, and this amount is remarkably decreased as compared with the amount of voids (within a range from 1.61 to 4.17%) of the liquid crystal polyester-impregnated base materials obtained in Comparative Examples 1 to 5. The results of a comparison between Example 5 in which the temperature of the step (3) is 140° C. (the amount of voids is 0.16%) and Comparative Example 2 in which the temperature is 120° C. which is only 20° C. lower than the above temperature (the amount of voids is 1.61%) revealed that the amount of voids of Example 5 is remarkably decreased as compared with Comparative Example 2. The same decreasing effect is also recognized in a comparison between Example 8 (the temperature of the step (3) is 140° C., and the amount of voids is 0.36%) and Comparative Example 5 (the temperature of the step (3) is 120° C., and the amount of voids is 2.75%).

Furthermore, the effects of the present invention are visually recognized based on FIG. 2 and FIG. 3. That is, in the liquid crystal polyester-impregnated base material 1 in FIG. 2 according to Example 4, the existence of voids is scarcely recognized at the position between warps 1a of the glass cloth, the position between wefts 1b of the glass cloth, and the position between the warp 1a and the weft 1b. To the contrary, in the liquid crystal polyester-impregnated base material 1′ in FIG. 3 according to Comparative Example 4, the existence of voids 2 is recognized at any position.

What is claimed is:

1. A method for producing a liquid crystal polyester-impregnated base material, which comprises the following steps of:
(1) impregnating a sheet-like base material composed of a fiber with a liquid composition containing 15 to 45% by mass of a liquid crystal polyester and 55 to 85% by mass of a solvent based on 100% by mass in total of the liquid crystal polyester and the solvent;
(2) allowing the base material impregnated with the liquid composition to pass through a pair of rolls having a distance which is smaller than the thickness of the base material; and
(3) heating the liquid crystal composition-impregnated base material passed through rolls at 140 to 250° C. for 60 to 600 seconds.

2. The method for producing a liquid crystal polyester-impregnated base material according to claim 1, wherein a heating time is from 120 to 600 seconds.

3. A printed circuit board comprising the liquid crystal polyester-impregnated base material produced by the method according to claim 1 as an insulating layer.
